(19) United States
(12) Patent Application Publication
(10) Pub. No.: US 2025/0084232 A1
(43) Pub. Date: Mar. 13, 2025

(54) LIQUID ENCAPSULATION RESIN COMPOSITION AND SEMICONDUCTOR DEVICE

(71) Applicant: Panasonic Intellectual Property Management Co., Ltd., Osaka (JP)

(72) Inventors: Taisuke YAMASHITA, Mie (JP); Hikaru OOHASI, Mie (JP); Atsushi KISANUKI, Mie (JP); Katsuya TANAKA, Aichi (JP)

(21) Appl. No.: 18/728,339

(22) PCT Filed: Jan. 11, 2023
(86) PCT No.: PCT/JP2023/000444

§ 371 Date: Jul. 11, 2024

(30) Foreign Application Priority Data
Jan. 18, 2022 (JP) 2022-005897

(51) Int. Cl. C08K 3/36; C08L 63/00; H01L 23/00

(52) U.S. Cl. CPC C08K 3/36; C08L 63/00; H01L 24/29; H01L 24/32; C08K 2201/005; H01L 24/73; H01L 2224/2919; H01L 2224/32225; H01L 2224/73204; H01L 2924/364

(57) ABSTRACT

A liquid encapsulation resin composition contains a silica (A), an epoxy resin (B), a curing agent (C), a curing accelerator (D), and a triblock copolymer (E) expressed by the formula (1): X−Y−X, where X is a segment block including a polymer of methyl methacrylate and Y is a segment block including a polymer of monomer components containing 2-ethylhexyl acrylate. The percentage of the triblock copolymer (E) to the total of the epoxy resin (B), the curing agent (C), and the curing accelerator (D) is equal to or greater than 1.0% by mass and equal to or less than 9.5% by mass.

### CROSS-REFERENCE OF RELATED APPLICATIONS

This application is the U.S. National Phase under 35 U.S.C. § 371 of International Patent Application No. PCT/JP2023/000444, filed on Jan. 11, 2023, which in turn claims the benefit of Japanese Patent Application No. 2022-005897, filed on Jan. 18, 2022, the entire disclosure of which Applications are incorporated by reference herein.

### TECHNICAL FIELD

The present disclosure generally relates to a liquid encapsulation resin composition and a semiconductor device, and more particularly relates to a liquid encapsulation resin composition and a semiconductor device including a cured product of the liquid encapsulation resin composition.

### BACKGROUND ART

Patent Literature 1 describes that a liquid resin composition used for encapsulation purposes, including an epoxy resin, a curing agent having an amino group, a high-molecular resin, and an inorganic filler, has a high degree of flowability at room temperature and may be used as an underfill material.

### CITATION LIST

### Patent Literature

Patent Literature 1: JP 2020-122161 A

### SUMMARY OF INVENTION

An object of the present disclosure is to provide a liquid encapsulation resin composition with the ability to decrease the elastic modulus of its cured product while increasing the flowability of an uncured product thereof and also provide a semiconductor device formed out of such a liquid encapsulation resin composition.

A liquid encapsulation resin composition according to an aspect of the present disclosure contains a silica (A), an epoxy resin (B), a curing agent (C), a curing accelerator (D), and a triblock copolymer (E) expressed by the following formula (1):

X—Y—X (1)

where X is a segment block configured as a polymer of methyl methacrylate and Y is a segment block configured as a polymer of monomer components containing 2-ethylhexyl acrylate. The percentage of the triblock copolymer (E) to the total of the epoxy resin (B), the curing agent (C), and the curing accelerator (D) is equal to or greater than 1.0% by mass and equal to or less than 9.5% by mass.

A semiconductor device according to another aspect of the present disclosure includes: a substrate; a semiconductor element; and an encapsulant filling a gap between the substrate and the semiconductor element. The encapsulant includes a cured product of the above-described liquid encapsulation resin composition.

### BRIEF DESCRIPTION OF DRAWINGS

FIG. 1 is a schematic cross-sectional view illustrating an exemplary semiconductor device fabricated by using a liquid encapsulation resin composition according to an exemplary embodiment of the present disclosure.

### DESCRIPTION OF EMBODIMENTS

### 1. Overview

First, it will be described exactly how the present inventors conceived the concept of the present disclosure.

In recent years, semiconductor devices, such as flip-chip ball grid arrays (FC-BGA), in each of which a chip and a substrate are bonded together with solder bumps, have been used extensively.

The semiconductor device includes an encapsulant for use to protect the semiconductor device from temperature and humidity variations and external forces. To make this encapsulant, an underfill material is used. The underfill material exhibits flowability at room temperature and therefore, may fill the gap between the chip and the substrate. After having filled the gap, the underfill material is heated and cured, thereby forming the encapsulant.

Patent Literature 1 describes that a liquid resin composition for encapsulation, including an epoxy resin, a curing agent having an amino group, a high-molecular resin, and an inorganic filler, has a high degree of flowability at room temperature and may be used as an underfill material. The liquid resin composition for encapsulation as disclosed in Patent Literature 1 certainly has excellent flowability before the resin composition is cured but the cured product thereof does not have a sufficiently low elastic modulus. That is to say, it is difficult for the liquid resin composition for encapsulation to provide a cured product with a sufficiently low elastic modulus while increasing the flowability of an uncured product thereof.

In view of the foregoing background, the present inventors carried out extensive research. As a result, the present inventors conceived the concept of a liquid encapsulation resin composition having the ability to decrease the elastic modulus of its cured product while increasing the flowability of an uncured product thereof.

Next, an embodiment of the present disclosure will be described. Note that the embodiment to be described below is only an example of the present disclosure and should not be construed as limiting. Rather, the embodiment may be readily modified in various manners depending on a design choice or any other factor without departing from the scope of the present disclosure.

A liquid encapsulation resin composition according to this embodiment (hereinafter simply referred to as a “liquid encapsulation resin composition”) and a semiconductor device including an encapsulant formed out of the liquid encapsulation resin composition will now be described.

The liquid encapsulation resin composition contains a silica (A), an epoxy resin (B), a curing agent (C), a curing accelerator (D), and a triblock copolymer (E) expressed by the following formula (1):

X—Y—X (1)

where X is a segment block configured as a polymer of methyl methacrylate and Y is a segment block configured as a polymer of monomer components containing 2-ethylhexyl acrylate. The percentage of the triblock copolymer (E) to the total of the epoxy resin (B), the curing agent (C), and the curing accelerator (D) is equal to or greater than 1.0% by mass and equal to or less than 9.5% by mass.

As for the triblock copolymer (E), the present inventors discovered via experiment that the glass transition temperature of the polymer that forms the segment block would affect the elastic modulus of a cured product of the liquid encapsulation resin composition.

This point will be described in detail. Generally speaking, a polymer formed by synthesizing together monomers with a high degree of steric hindrance (such as methyl methacrylate) has had its rigidity increased moderately, and therefore, has had its glass transition temperature increased moderately as well. The triblock copolymer (E) has, at both terminals thereof, a segment block configured as a polymer having such a moderately increased glass transition temperature, and therefore, may contribute to increasing the durability of a cured product of the liquid encapsulation resin composition to temperature variations. In addition, a polymer formed by synthesizing together monomers having a substituent group with a moderately high degree of steric hindrance and high flexibility, such as either butyl acrylate or 2-ethylhexyl acrylate, has its movement restricted moderately and has had its flexibility increased, and therefore, has had its glass transition temperature lowered to a moderate degree. The triblock copolymer (E) has a segment block configured as a polymer having such a moderately lowered glass transition temperature, and therefore, may decrease the elastic modulus of a cured product of the liquid encapsulation resin composition. That is to say, the triblock copolymer (E) expressed by the Formula (1), where X is a segment block configured as a polymer of methyl methacrylate and Y is a segment block configured as a polymer of monomer components containing 2-ethylhexyl acrylate, may decrease the elastic modulus of a cured product of the liquid encapsulation resin composition while ensuring sufficient durability to temperature variations for the cured product of the liquid encapsulation resin composition.

In addition, according to the present disclosure, the percentage of the triblock copolymer (E) to the total of the epoxy resin (B), the curing agent (C), and the curing accelerator (D) is equal to or greater than 1.0% by mass and equal to or less than 9.5% by mass. Adjusting the percentage of the triblock copolymer (E) to a particular numerical value range enables not only decreasing the elastic modulus of a cured product of the liquid encapsulation resin composition sufficiently but also ensuring sufficient flowability for an uncured product thereof.

The liquid encapsulation resin composition may provide a cured product maintaining a high degree of flowability even at room temperature and yet having a low elastic modulus. A liquid encapsulation resin composition having such properties may be used effectively as an underfill material for fabricating a semiconductor device. In particular, this liquid encapsulation resin composition has a high degree of flowability at room temperature as described above, and therefore, may be used effectively as a capillary underfill material.

A semiconductor device according to this embodiment is formed out of the liquid encapsulation resin composition. That is to say, the semiconductor device according to this embodiment includes a cured product of the liquid encapsulation resin composition. More specifically, the semiconductor device includes a substrate, a semiconductor element, and an encapsulant filling the gap between the substrate and the semiconductor element. The encapsulant includes a cured product of the liquid encapsulation resin composition. Adding the cured product of the liquid encapsulation resin composition to the encapsulant causes a decrease in the elastic modulus of the encapsulant in the semiconductor device, increases the durability of the encapsulant to temperature variations, and eventually, may reduce the chances of causing cracks at corner portions of the die included in the semiconductor device.

### 2. Details of Liquid Encapsulation Resin Composition

Next, the liquid encapsulation resin composition according to this embodiment will be described in further detail.

### 2.1 Chemical Makeup

### Silica (A)

The liquid encapsulation resin composition according to this embodiment contains a silica (A) as described above. Examples of specific types of silica (A) include a fused silica and a crystalline silica. Among other things, the silica (A) is preferably a fused silica. Also, the silica (A) contained in the liquid encapsulation resin composition may be either a single type of silica or a combination of two or more types of silica.

The silica (A) preferably has a spherical shape. That is to say, the silica (A) is preferably a spherical fused silica. This allows the liquid encapsulation resin composition to maintain a high degree of flowability.

The maximum particle size of the silica (A) is preferably equal to or less than 10.0 μm. This allows the liquid encapsulation resin composition to maintain a high degree of flowability. The maximum particle size of the silica (A) is more preferably equal to or less than 5.0 μm and even more preferably equal to or less than 3.0 μm. Meanwhile, the maximum particle size of the silica (A) is preferably equal to or greater than 0.1 μm and more preferably equal to or greater than 0.3 μm.

Note that the maximum particle size of the silica (A) refers to a volume based maximum particle size calculated based on measured values of a particle size distribution by the laser diffraction and scattering method. The maximum particle size of the silica (A) may be measured using a particle size analyzer (model number “MT3300EXII” manufactured by MicrotracBEL Corporation).

Also, the mean particle size of the silica (A) is preferably equal to or less than 10.0 μm, and more preferably equal to or less than 5.0 μm. Meanwhile, the mean particle size of the silica (A) is preferably equal to or greater than 0.1 μm and more preferably equal to or greater than 0.2 μm.

Note that the mean particle size of the silica (A) refers to a volume-based median diameter calculated based on measured values of a particle size distribution by the laser diffraction method. The mean particle size of the silica (A) may be measured using the particle size analyzer (model number “MT3300EXII” manufactured by MicrotracBEL Corporation).

The percentage of the silica (A) to the liquid encapsulation resin composition is preferably equal to or greater than 40.0% by mass and equal to or less than 80.0% by mass. This enables not only decreasing the elastic modulus of a cured product of the liquid encapsulation resin composition but also adjusting the coefficient of linear expansion thereof to a desired numerical value. In particular, setting the percentage of the silica (A) to the liquid encapsulation resin composition at a value equal to or greater than 40.0% by mass enables maintaining a state where the silica (A) is uniformly dispersed in the liquid encapsulation resin composition while the liquid encapsulation resin composition is filling the gap between the substrate and the element. This allows, when the liquid encapsulation resin composition is used as an underfill material, the silica (A) to be dispersed uniformly in the underfill material.

The percentage of the silica (A) to the liquid encapsulation resin composition is more preferably equal to or greater than 42.0% by mass and even more preferably equal to or greater than 45.0% by mass. Meanwhile, the percentage of the silica (A) to the liquid encapsulation resin composition is more preferably equal to or less than 75.0% by mass and even more preferably equal to or less than 70.0% by mass.

### Epoxy Resin (B)

The liquid encapsulation resin composition according to this embodiment contains an epoxy resin (B) as described above. The epoxy resin (B) imparts curability and adhesiveness to the liquid encapsulation resin composition and thereby imparts durability and heat resistance to a cured product of the liquid encapsulation resin composition.

Specifically, the epoxy resin (B) includes at least one selected from the group consisting of: diglycidyl ether epoxy resins such as naphthalene epoxy resins, bisphenol A epoxy resins, bisphenol F epoxy resins, bisphenol AD epoxy resins, bisphenol S epoxy resins, and hydrogenated bisphenol A epoxy resins; epoxy resins obtained by epoxidizing a novolac resin produced by causing a phenol such as an ortho cresol novolac epoxy resin to react with an aldehyde; glycidyl ester epoxy resins obtained by causing a polybasic acid such as phthalic acid or a dimer acid to react with epichlorohydrin; and glycidyl amine epoxy resins obtained by causing an amine compound such as diaminodiphenylmethane and isocyanuric acid to react with epichlorohydrin.

The epoxy resin (B) is preferably in liquid form at 25° C. from the viewpoint of flowability. This enables lowering the viscosity of the liquid encapsulation resin composition. Optionally, in this embodiment, an epoxy resin which is in solid form at 25° C. may also be used in combination as long as the flowability of the liquid encapsulation resin composition is not affected by the epoxy resin. As used herein, the expression “the epoxy resin (B) is in liquid form at 25° C.” means that the viscosity of the epoxy resin (B) at 25° C. is equal to or less than 1000 Pa·s.

Also, the viscosity of the epoxy resin (B) at 25° C. is preferably equal to or greater than 0.01 Pa·s and more preferably equal to or greater than 0.02 Pa·s. Meanwhile, the viscosity of the epoxy resin (B) at 25° C. is preferably equal to or less than 50.0 Pa·s and more preferably equal to or less than 20.0 Pa·s. Setting the viscosity of the epoxy resin (B) at a value falling within any of these ranges enables further decreasing the elastic modulus of a cured product of the liquid encapsulation resin composition while further increasing the flowability of an uncured product thereof.

The weight average molecular weight (Mw) of the epoxy resin (B) preferably falls within a range in which the flowability of the liquid encapsulation resin composition is not allowed to decrease. The weight average molecular weight (Mw) of the epoxy resin (B) is preferably equal to or greater than 100 and more preferably equal to or greater than 150. Meanwhile, the weight average molecular weight (Mw) of the epoxy resin (B) is preferably equal to or less than 1500 and more preferably equal to or less than 750.

The weight average molecular weight (Mw) of the epoxy resin (B) may be measured, for example, by gel permeation chromatography (GPC) and through conversion using a standard polystyrene calibration curve.

Optionally, a commercially available product may also be used as the epoxy resin (B). Examples of commercially available epoxy resins (B) include a bisphenol F epoxy resin manufactured by Nippon Steel & Sumikin Chemical Co., Ltd. (product name: YDF-8170C and having an epoxy equivalent of 155 to 165 g/eq), a bisphenol A epoxy resin manufactured by Nippon Steel & Sumikin Chemical Co., Ltd. (product name: YD-128 and having an epoxy equivalent of 184 to 194 g/eq), and a polyfunctional epoxy resin manufactured by Mitsubishi Chemical Corporation (product name: jER-630 and having an epoxy equivalent of 90 to 105 g/eq). The epoxy resin (B) used may be either a single type of epoxy resin or a combination of two or more types of epoxy resins, whichever is appropriate. The epoxy equivalent of the epoxy resin (B) is preferably equal to or greater than 100 g/eq and equal to or less than 1000 g/eq.

### Curing Agent (C)

A liquid encapsulation resin composition according to this embodiment contains a curing agent (C) as described above.

As the curing agent (C), an agent which allows the epoxy resin (B) to be cured may be used. Also, the curing agent (C) may be in liquid form or solid form, whichever is appropriate, as long as the curing agent (C) allows, when included in the liquid encapsulation resin composition, the liquid encapsulation resin composition to exhibit flowability at 25° C. Note that if the liquid encapsulation resin composition contains, as the curing agent (C), a curing agent taking liquid form at 25° C., the flowability of the liquid encapsulation resin composition tends to increase.

Examples of the curing agent (C) include amine-based curing agents such as chain aliphatic amines, cyclic aliphatic amines, aliphatic aromatic amines, and aromatic amines. As a specific compound, the curing agent (C) includes at least one selected from the group consisting of, for example: chain aliphatic amines such as diethylenetriamine, triethylenetetramine, tetraethylenepentamine, dipropylenediamine, diethylaminopropylamine, hexamethylenediamine, and 1,2-bis(2-aminoethoxy) ethane; cyclic aliphatic amines such as N-aminoethylpiperazine, menthenediamine, isophoronediamine, diaminodicyclohexylmethane, and 1,3-diaminomethylcyclohexane; aliphatic aromatic amines such as m-xylylenediamine; aromatic amines, each having one aromatic ring, such as metaphenylenediamine, 1,3-diaminotoluene, 1,4-diaminotoluene, 2,4-diaminotoluene, 3,5-diethyl-2,4-diaminotoluene, 3,5-diethyl-2,6-diaminotoluene, and 2,4-diaminoanisole; aromatic amines, each having two aromatic rings, such as 2,4′-diaminodiphenylmethane, 4,4′-diaminodiphenylsulfone, 4,4′-methylenebis(2-ethylaniline), 3,3-diethyl-4,4′-diaminodiphenylmethane, 3,3′,5,5′-tetramethyl-4,4′-diaminodiphenylmethane, 3,3′,5,5′-tetraethyl-4,4′-diaminodiphenylmethane, and polytetramethylene oxide di-para-aminobenzoate; condensates of an aromatic diamine and epichlorohydrin; and reaction products of an aromatic diamine and styrene.

For example, a commercially available product may be used as the curing agent (C). Examples of the commercially available curing agent (C) include an amine curing agent manufactured by Nippon Kayaku Co., Ltd. (product name: Kayahard-AA and having an amine equivalent of 64 g/eq) and a modified aromatic amine-based curing agent manufactured by ADEKA Corporation (product name: EH-105L and having an amine equivalent of 61 g/eq).

It is preferable that the curing agent (C) contain an aromatic amine among the amine curing agents cited above. That is to say, the curing agent (C) preferably contains an aromatic amine-based curing agent (C-1). Also, the amine equivalent of the aromatic amine-based curing agent (C-1) is preferably equal to or greater than 20 g/eq and equal to or less than 500 g/eq.

In the liquid encapsulation resin composition according to this embodiment, the functional group equivalent ratio of the epoxy resin (B) to the curing agent (C) is preferably equal to or greater than 0.6 and equal to or less than 1.4. This allows the curing agent (C) and the epoxy resin (B) to react so efficiently with each other as to reduce the chances of leaving these compounds unreacted, thus enabling improving the heat resistance reliability of a semiconductor device fabricated by using the liquid encapsulation resin composition. As used herein, the epoxy resin's (B) own functional group refers to an epoxy group and the curing agent's (C) own functional group refers to an amino group. That is to say, the ratio of the number of equivalents of the epoxy groups included in the epoxy resin (B) to the number of equivalents of the amino groups included in the curing agent (C) is preferably equal to or greater than 0.6 and equal to or less than 1.4. Also, the functional group equivalent ratio of the epoxy resin (B) to the curing agent (C) is more preferably equal to or greater than 0.7 and even more preferably equal to or greater than 0.8. Meanwhile, the functional group equivalent ratio of the epoxy resin (B) to the curing agent (C) is preferably equal to or less than 1.3.

Optionally, the curing agent (C) may include not only the amine-based curing agent described above but also an additional curing agent other than the amine-based one. Examples of the additional curing agent include phenolic curing agents, acid anhydride curing agents, and carboxylic acid dihydrazide curing agents.

### Curing Accelerator (D)

The liquid encapsulation resin composition according to this embodiment contains a curing accelerator (D) as described above.

The curing accelerator (D) is generally used in, for example, an epoxy resin composition to promote the curing reaction between the epoxy resin (B) and the curing agent (C). Examples of such curing accelerators (D) include various amine-based compounds, imidazole-based compounds such as 2-ethyl-4-methylimidazole, organophosphine-based compounds, quaternary ammonium, and phosphonium-based compounds. As more specific compounds, the curing accelerator (D) includes at least one selected from the group consisting of, for example, cycloamidine compounds such as 1,8-diaza-bicyclo [5.4.0] undecene-7,1,5-diaza-bicyclo [4.3.0] nonene and 5,6-dibutylamino-1,8-diaza-bicyclo [5.4.0] undecene-7; tertiary amine compounds such as triethylenediamine, benzyldimethylamine, triethanolamine, dimethylaminoethanol, and tris(dimethylaminomethyl) phenol; imidazole compounds such as 2-methylimidazole, 2-ethyl-4-methylimidazole, 2-phenylimidazole, 2-phenyl-4-methylimidazole, 1-benzyl-2-phenylimidazole, 1-benzyl-2-methylimidazole, 2-phenyl-4,5-dihydroxymethylimidazole, 2-phenyl-4-methyl-5-hydroxymethylimidazole, 2,4-diamino-6-(2′-methylimidazolyl-(1′))-ethyl-s-triazine, and 2-heptadecylimidazole; trialkylphosphines such as tributylphosphine; dialkylarylphosphine such as dimethylphenylphosphine; alkyldiarylphosphines such as methyldiphenylphosphine; organic phosphines such as triphenylphosphine and alkyl group-substituted triphenylphosphine, and phenyl-boron salts such as 2-ethyl-4-methylimidazole tetraphenyl borate and N-methylmorpholine tetraphenylborate.

The percentage of the curing accelerator (D) to the total of the epoxy resin (B) and the curing agent (C) is preferably equal to or greater than 0.01% by mass, and more preferably equal to or greater than 0.05% by mass. Meanwhile, the percentage of the curing accelerator (D) to the total of the epoxy resin (B) and the curing agent (C) is preferably equal to or less than 5.0% by mass, and more preferably equal to or less than 1.0% by mass.

### Triblock Copolymer (E)

The liquid encapsulation resin composition according to this embodiment contains, as described above, the triblock copolymer (E) expressed by the following formula (1):

X—Y—X (1)

where X is a segment block configured as a polymer of methyl methacrylate and Y is a segment block configured as a polymer of monomer components containing 2-ethylhexyl acrylate. Adding the triblock copolymer (E) to the liquid encapsulation resin composition enables decreasing the elastic modulus of a cured product of the liquid encapsulation resin composition while ensuring sufficient durability to temperature variations for the cured product of the liquid encapsulation resin composition.

For example, the segment block configured as a polymer of methyl methacrylate has a higher glass transition temperature than a segment block configured as a polymer of monomer components containing 2-ethylhexyl acrylate. In other words, in the triblock copolymer (E), X is the harder part with the higher glass transition temperature (i.e., a hard segment block) while Y is the softer part with the lower glass transition temperature (i.e., a soft segment block). As used herein, the glass transition temperature of a segment block refers to the glass transition temperature of a polymer consisting of the segment block alone.

Also, further adding butyl acrylate to the monomer components enables further decreasing the elastic modulus of a cured product of the liquid encapsulation resin composition. That is to say, in the formula (1), Y is more preferably a segment block configured as a polymer of butyl acrylate and 2-ethylhexyl acrylate.

Optionally, the segment block configured as the polymer of methyl methacrylate may include not only methyl methacrylate but also a residue of monomers other than methyl methacrylate as long as an object of this embodiment is achievable. The proportion of the residue of methyl methacrylate to all residues of monomers that form the segment block of X is preferably equal to or higher than 60 mol %. In the same way, the segment block configured as a polymer of monomer components containing 2-ethylhexyl acrylate may include not only either 2-ethylhexyl acrylate or 2-ethylhexyl acrylate and butyl acrylate but also a residue of monomers other than 2-ethylhexyl acrylate and butyl acrylate as long as an object of this embodiment is achievable. The proportion in total of the residues of 2-ethylhexyl acrylate and butyl acrylate to all residues of the monomers that form the segment block Y is preferably equal to or higher than 60 mol %.

The weight average molecular weight (Mw) of the triblock copolymer (E) is preferably equal to or greater than 40,000 and equal to or less than 100,000. Setting the molecular weight of the triblock copolymer (E) at a value falling within this range enables decreasing the elastic modulus of a cured product of the liquid encapsulation resin composition while increasing the flowability of an uncured product thereof. The weight average molecular weight (Mw) of the triblock copolymer (E) is more preferably equal to or greater than 45,000. The weight average molecular weight (Mw) of the triblock copolymer (E) is more preferably equal to or less than 90,000, and even more preferably equal to or less than 80,000. The weight average molecular weight (Mw) of the triblock copolymer (E) may be measured, for example, by gel permeation chromatography (GPC) and through conversion using a standard polystyrene calibration curve.

The percentage of the block part X in the formula (1) to the triblock copolymer (E) is preferably equal to or greater than 10.0% by mass and more preferably equal to or greater than 14.0% by mass. Meanwhile, the percentage of the block part X in the formula (1) to the triblock copolymer (E) is preferably equal to or less than 60.0% by mass and more preferably equal to or less than 50.0% by mass. Setting the percentage of the block part X in the formula (1) to the triblock copolymer (E) at a value falling within any of these numerical value ranges enables further decreasing the elastic modulus of a cured product of the liquid encapsulation resin composition while further increasing the flowability of an uncured product thereof.

Optionally, as the triblock copolymer (E), a commercially available product may be used, for example. Examples of such commercially available products of the triblock copolymer (E) include Clarity (R) KL-LK9333 and Clarity (R) LK9243 (both manufactured by Kuraray Co., Ltd.).

The percentage of the triblock copolymer (E) to the total of the epoxy resin (B) and the triblock copolymer (E) is preferably equal to or greater than 0.5% by mass and equal to or less than 8.0% by mass. This enables further decreasing the elastic modulus of a cured product of the liquid encapsulation resin composition while further increasing the flowability of an uncured product thereof. Moreover, the percentage of the triblock copolymer (E) to the total of the epoxy resin (B) and the triblock copolymer (E) is more preferably equal to or greater than 1.0% by mass.

Also, as described above, the percentage of the triblock copolymer (E) to the total of the epoxy resin (B), the curing agent (C), and the curing accelerator (D) is equal to or greater than 1.0% by mass and equal to or less than 9.5% by mass. This enables not only decreasing the elastic modulus of a cured product of the liquid encapsulation resin composition sufficiently but also ensuring sufficient flowability for an uncured product of the liquid encapsulation resin composition. More specifically, setting the percentage of the triblock copolymer (E) to the total of the epoxy resin (B), the curing agent (C), and the curing accelerator (D) at a value equal to or greater than 1.0% by mass does not make the percentage of the triblock copolymer (E) too small. This allows the elastic modulus of a cured product of the liquid encapsulation resin composition to be decreased sufficiently. Also, setting the percentage of the triblock copolymer (E) to the total of the epoxy resin (B), the curing agent (C), and the curing accelerator (D) at a value equal to or less than 9.5% by mass does not make the percentage of the triblock copolymer (E) too large. This allows the flowability of an uncured product of the liquid encapsulation resin composition to be increased sufficiently. The percentage of the triblock copolymer (E) to the total of the epoxy resin (B), the curing agent (C), and the curing accelerator (D) is preferably equal to or less than 8.0% by mass, and more preferably equal to or less than 6.0% by mass.

### Other Materials

The liquid encapsulation resin composition according to this embodiment may include not only the materials described above but also at least one selected from the group consisting of, for example, a coupling agent, a coloring agent, a thixotropic agent, an ion trapping agent, an antifoaming agent, a leveling agent, and an antioxidant, as long as the object of the present disclosure is achievable.

The liquid encapsulation resin composition according to this embodiment may contain a coupling agent as described above. The coupling agent improves compatibility between the silica (A), the epoxy resin (B), and the triblock copolymer (E), for example. The coupling agent includes at least one selected from the group consisting of, for example, silane-based compounds, titanium-based compounds, aluminum chelates, and aluminum/zirconium-based compounds.

The silane-based compound includes at least one selected from the group consisting of, for example, silane compounds having an amino group, epoxysilanes, mercaptosilanes, alkylsilanes, ureidosilanes, and vinylsilanes.

More specifically, the silane-based compound includes at least one selected from the group consisting of, for example, vinyltrichlorosilane, vinyltriethoxysilane, vinyl tris (β-methoxyethoxy) silane, γ-methacryloxypropyl trimethoxysilane, β-(3,4-epoxycyclohexyl) ethyltrimethoxysilane, γ-glycidoxypropyl trimethoxysilane, γ-glycidoxypropyl methyl-dimethoxysilane, vinyltriacetoxysilane, γ-mercaptopropyl trimethoxysilane, γ-aminopropyl trimethoxysilane, γ-aminopropylmethyl dimethoxysilane, γ-aminopropyl triethoxysilane, γ-aminopropylmethyl diethoxysilane, γ-anilinopropyl trimethoxysilane, γ-anilinopropyl triethoxysilane, γ-(N,N-dimethyl) aminopropyl trimethoxysilane, γ-(N,N-diethyl) aminopropyl trimethoxysilane, γ-(N,N-dibutyl) aminopropyl trimethoxysilane, γ-(N-methyl) anilinopropyl trimethoxysilane, γ-(N-ethyl) anilinopropyl trimethoxysilane, γ-(N,N-dimethyl) aminopropyl triethoxysilane, γ-(N,N-diethyl) aminopropyl triethoxysilane, γ-(N,N-dibutyl) aminopropyl triethoxysilane, γ-(N-methyl) anilinopropyl triethoxysilane, γ-(N-ethyl) anilinopropyl triethoxysilane, γ-(N,N-dimethyl) aminopropylmethyl dimethoxysilane, γ-(N,N-diethyl) aminopropylmethyl dimethoxysilane, γ-(N,N-dibutyl) aminopropylmethyl dimethoxysilane, γ-(N-methyl) anilinopropylmethyl dimethoxysilane, γ-(N-ethyl) anilinopropylmethyl dimethoxysilane, N-(trimethoxysilylpropyl) ethylenediamine, N-(dimethoxymethylsilylisopropyl) ethylenediamine, methyltrimethoxysilane, dimethyldimethoxysilane, methyltriethoxysilane, γ-chloropropyl-trimethoxysilane, hexamethyldisilane, vinyltrimethoxysilane, and γ-mercaptopropylmethyl dimethoxysilane.

In addition, the titanium-based compound includes at least one selected from the group consisting of, for example, isopropyl triisostearoyl titanate, isopropyl tris (dioctylpyrophosphate) titanate, isopropyl tri (N-aminoethyl-aminoethyl) titanate, tetraoctyl bis (ditridecylphosphite) titanate, tetra (2,2-diallyloxymethyl-1-butyl) bis (ditridecyl) phosphite titanate, bis (dioctylpyrophosphate) oxyacetate titanate, bis (dioctyl pyrophosphate) ethylene titanate, isopropyl trioctanoyl titanate, isopropyl dimethacrylic isostearoyl titanate, isopropyl tridodecyl benzene sulfonyl titanate, isopropyl isostearoyl diacrylic titanate, isopropyl tri (dioctyl phosphate) titanate, isopropyl tricumylphenyl titanate, and tetraisopropyl bis (dioctyl phosphite) titanate.

The liquid encapsulation resin composition according to this embodiment may contain a coloring agent as described above.

Specific examples of the coloring agent include inorganic pigments and organic dyes.

The inorganic pigment includes, for example, at least one selected from the group consisting of, for example, carbon black, a composite metal oxide of copper, chromium, and manganese, a composite metal oxide of iron and manganese, a composite metal oxide of chromium and iron, a composite metal oxide of cobalt, iron, and chromium, a composite metal oxide of copper, iron, manganese, and aluminum, and titanium oxide. Also, the organic dye includes at least one selected from the group consisting of alloy dyes such as azo compound chromium complexes, azo dyes, anthraquinone dyes, and nigrosine dyes. One of these coloring agents may be used by itself. Alternatively, two or more types of coloring agents selected from this group may be used in combination.

### Method for Manufacturing Liquid Encapsulation Resin Composition

The liquid encapsulation resin composition according to this embodiment may be manufactured by any method without limitation as long as the method allows the above-described components to be uniformly dispersed and mixed together. Examples of specific dispersion and mixing methods include a method for dispersing and kneading those components using a three-roll mixer or a planetary mixer, for example.

### 2.2 Properties

Next, the properties of the liquid encapsulation resin composition according to this embodiment will be described in detail.

The liquid encapsulation resin composition has the above-described chemical makeup, and therefore, may exhibit such properties. Thus, the liquid encapsulation resin composition may be used effectively as an underfill material for fabricating a semiconductor device. In recent years, semiconductor devices tends to have an increased chip size (chip size enlargement), a narrowed gap between the semiconductor element and the substrate (gap narrowing), and a narrower pitch between bumps (fine pitch trend). The liquid encapsulation resin composition according to this embodiment is also applicable as an underfill material to even such semiconductor devices and allows such semiconductor devices to exhibit good encapsulation performance. Examples of the “semiconductor elements” as used herein include active components such as chips, transistors, diodes, and thyristors, and passive components such as capacitors, resistors, and coils.

The liquid encapsulation resin composition preferably has, at 25° C., a viscosity equal to or greater than 1.0 Pa·s and equal to or less than 50.0 Pa·s. This makes it easier to use the liquid encapsulation resin composition as a material for fabricating the semiconductor device. In particular, setting the viscosity at 25° C. of the liquid encapsulation resin composition at a value equal to or less than 50 Pa·s makes it easier to handle the liquid encapsulation resin composition. The liquid encapsulation resin composition more preferably has, at 25° C., a viscosity equal to or greater than 5.0 Pa·s. Meanwhile, the liquid encapsulation resin composition more preferably has, at 25° C., a viscosity equal to or less than 45.0 Pa·s and even more preferably a viscosity equal to or less than 40.0 Pa·s.

The viscosity of the liquid encapsulation resin composition was measured using, for example, a Brookfield viscometer (model number “TVB-10” manufactured by Toki Sangyo Co., Ltd.) with the temperature set at 25° C. and the number of revolutions set at 10.0 rpm.

The liquid encapsulation resin composition preferably has a thixotropic index equal to or greater than 0.5 and equal to or less than 1.2. The thixotropic index is calculated based on the viscosity of the liquid encapsulation resin composition at 25° C. This tends to increase the applicability of the liquid encapsulation resin composition to the target. In addition, this also tends to, when fabricating the semiconductor device, increase the fillability of the liquid encapsulation resin composition into the gap between the semiconductor element and the substrate.

The thixotropic index may be measured by, for example, the viscosity measuring method using a Brookfield viscometer. Specifically, the thixotropic index may be calculated as the ratio of the result of measurement of the viscosity at 25° C. and the number of revolutions of 1.0 rpm to the result of measurement of the viscosity at 25° C. and the number of revolutions of 10.0 rpm (i.e., the viscosity at 1.0 rpm/the viscosity at 10.0 rpm).

Also, the liquid encapsulation resin composition more preferably has a thixotropic index equal to or greater than 0.6 at 25° C.

The liquid encapsulation resin composition preferably has, at a temperature equal to or higher than 90° C. and equal to or lower than 170° C., a viscosity equal to or greater than 0.01 Pa·s and equal to or less than 1.00 Pa·s. This makes it easier to use the liquid encapsulation resin composition as a material for fabricating the semiconductor device. More specifically, setting the viscosity of the liquid encapsulation resin composition at a value falling within this viscosity range at a temperature falling within this temperature range makes it easier to fill the gap between the semiconductor element and the substrate while fabricating the semiconductor device. Consequently, this allows the encapsulant included in the semiconductor device to fully exert its encapsulation performance.

The liquid encapsulation resin composition more preferably has, at a temperature equal to or higher than 90° C. and equal to or lower than 170° C., a viscosity equal to or greater than 0.03 Pa·s and even more preferably has a viscosity equal to or greater than 0.05 Pa·s. Meanwhile, the liquid encapsulation resin composition more preferably has, at a temperature equal to or higher than 90° C. and equal to or lower than 170° C., a viscosity equal to or less than 0.80 Pa·s and even more preferably has a viscosity equal to or less than 0.40 Pa·s.

The time it takes for the liquid encapsulation resin composition heated to 90° C. to infiltrate the gap, which is adjusted at 20 μm, between two glass panes to a depth of 20 mm (hereinafter referred to as an “infiltration time”) is preferably within 15 minutes. This infiltration time is more preferably within 12 minutes and even more preferably within 10 minutes.

A cured product of the liquid encapsulation resin composition preferably has an elastic modulus equal to or greater than 2.0 GPa and equal to or less than 8.0 GPa. This enables improving the performance of the encapsulant including a cured product of the liquid encapsulation resin composition which is included in the semiconductor device. The cured product of the liquid encapsulation resin composition more preferably has an elastic modulus equal to or greater than 3.0 GPa. Meanwhile, the cured product of the liquid encapsulation resin composition more preferably has an elastic modulus equal to or less than 7.0 GPa and even more preferably has an elastic modulus equal to or less than 6.5 GPa.

### 3. Exemplary Application of Liquid Encapsulation Resin Composition

An exemplary application of the liquid encapsulation resin composition according to this embodiment will now be described in detail.

The liquid encapsulation resin composition according to this embodiment may be used as an underfill material for use to fill the gap between a semiconductor element and the substrate when a semiconductor device is fabricated as described above. More specifically, the liquid encapsulation resin composition may be used as an underfill material to fill the gap between the substrate and a chip to be flip-chip bonded at a package level such as a flip-chip ball grid array (FC-BGA), an enhanced GBA (EBGA), an advanced BGA (ABGA), a stacked BGA, and a system in package (SIP). In particular, the liquid encapsulation resin composition according to this embodiment has such a high degree of flowability as to be applicable to a capillary underfilling process. That is to say, the liquid encapsulation resin composition according to this embodiment is used as a capillary underfill material. As used herein, the “capillary underfilling process” refers to a method for impregnating and permeating the underfill material into the gap between the semiconductor element such as a chip and the substrate through capillary action by applying an underfill material through a capillary as fine as an injector needle from around the semiconductor element such as a chip. Recently, there have been growing trends toward chip size enlargement, gap narrowing, and pitch reduction (fine pitch trend) as described above. Nevertheless, the liquid encapsulation resin composition according to this embodiment is also applicable to even a situation where the chip size is equal to or greater than 20×20 mm, the gap between the semiconductor element such as a chip and the substrate is equal to or less than 50 μm, and/or the pitch between bumps in the semiconductor device is equal to or less than 150 μm, thus enabling fabricating a semiconductor device with excellent encapsulation performance.

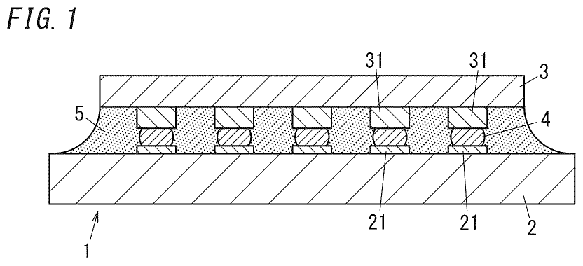

FIG. 1 illustrates an exemplary semiconductor device 1 fabricated by applying the liquid encapsulation resin composition according to this embodiment to the capillary underfilling process.

This semiconductor device 1 includes a substrate 2, a semiconductor element 3 which has been mounted to face the substrate 2 via bumps 4, and an encapsulant 5 that hermetically closes the gap between the substrate 2 and the semiconductor element 3. The encapsulant 5 includes a cured product of the liquid encapsulation resin composition. The semiconductor element 3 includes a plurality of bump electrodes 31 on a surface thereof facing the substrate 2. On the other hand, the substrate 2 has conductor wiring 21 on a surface thereof facing the semiconductor element 3. The bump electrodes 31 and the conductor wiring 21 are aligned with each other and connected to each other via the bumps 4. The bumps 4, the bump electrodes 31, and the conductor wiring 21 are all embedded in the encapsulant 5.

The encapsulant 5 includes a cured product of the liquid encapsulation resin composition as described above. In other words, the encapsulant 5 is formed by filling the gap between the substrate 2 and semiconductor element 3 of the semiconductor device 1 with the liquid encapsulation resin composition and then heating and curing the liquid encapsulation resin composition. A method for forming the encapsulant 5 will be described in further detail. First, the liquid encapsulation resin composition is dripped through a syringe, for example, onto one side of a side surface of the semiconductor element 3. This causes the liquid encapsulation resin composition to fill the gap, which is not closed with any of the bumps 4, between the semiconductor element 3 and the substrate 2 through capillary action. In this case, heating the substrate 2 with a heater such as a hot plate would transfer the heat of the substrate 2 to the liquid encapsulation resin composition, thus allowing the gap to be filled efficiently with the liquid encapsulation resin composition. That is why the liquid encapsulation resin composition that is filling the gap of the semiconductor device 1 preferably has a temperature equal to or higher than 80° C. and equal to or lower than 130° C. Subsequently, after the liquid encapsulation resin composition has infiltrated and filled the gap fully without leaving any air gap, the semiconductor device 1 is heated in a constant temperature bath, for example, thereby forming the encapsulant 5.

As can be seen from the foregoing description, the semiconductor device 1 according to this embodiment includes the encapsulant 5 formed by the above-described method, the substrate 2, and the semiconductor element 3. Note that this is only an exemplary method for forming the encapsulant 5 and should not be construed as limiting. That is to say, any other appropriate method may also be employed to form the encapsulant 5 as long as the semiconductor device 1 is allowed to exhibit good encapsulation performance.

### 4. Recapitulation

As can be seen from the foregoing description of exemplary embodiments, the present disclosure has the following aspects. In the following description, reference signs are added in parentheses to the respective constituent elements solely for the purpose of clarifying the correspondence between those aspects of the present disclosure and the exemplary embodiments described above.

A liquid encapsulation resin composition according to a first aspect of the present disclosure contains a silica (A), an epoxy resin (B), a curing agent (C), a curing accelerator (D), and a triblock copolymer (E) expressed by the following formula (1):

X—Y—X (1)

where X is a segment block configured as a polymer of methyl methacrylate and Y is a segment block configured as a polymer of monomer components containing 2-ethylhexyl acrylate. The percentage of the triblock copolymer (E) to the total of the epoxy resin (B), the curing agent (C), and the curing accelerator (D) is equal to or greater than 1.0% by mass and equal to or less than 9.5% by mass.

The first aspect enables providing a liquid encapsulation resin composition with the ability to decrease the elastic modulus of its cured product while increasing the flowability of an uncured product thereof.

In a liquid encapsulation resin composition according to a second aspect of the present disclosure, which may be implemented in conjunction with the first aspect, the monomer components further contain butyl acrylate.

The second aspect may further decrease the elastic modulus of a cured product of the liquid encapsulation resin composition.

In a liquid encapsulation resin composition according to a third aspect of the present disclosure, which may be implemented in conjunction with the first or second aspect, the triblock copolymer (E) has a weight average molecular weight equal to or greater than 40,000 and equal to or less than 100,000.

The third aspect enables decreasing the elastic modulus of a cured product of the liquid encapsulation resin composition while increasing the flowability of an uncured product thereof.

In a liquid encapsulation resin composition according to a fourth aspect of the present disclosure, which may be implemented in conjunction with any one of the first to third aspects, the epoxy resin (B) is in liquid form at 25° C.

The fourth aspect enables decreasing the viscosity of the liquid encapsulation resin composition.

In a liquid encapsulation resin composition according to a fifth aspect of the present disclosure, which may be implemented in conjunction with any one of the first to fourth aspects, the curing agent (C) contains an aromatic amine-based curing agent (C-1).

The fifth aspect may ensure not only a high degree of flowability before the resin composition is cured but also a low elastic modulus after the resin composition has been cured (i.e., for its cured product).

In a liquid encapsulation resin composition according to a sixth aspect of the present disclosure, which may be implemented in conjunction with any one of the first to fifth aspects, a functional group equivalent ratio of the epoxy resin (B) to the curing agent (C) is equal to or greater than 0.6 and equal to or less than 1.4.

The sixth aspect allows the curing agent (C) and the epoxy resin (B) to react with each other so efficiently as to reduce the chances of leaving these compounds unreacted. Consequently, this enables improving the reliability in heat resistance of a semiconductor device (1) fabricated by using this liquid encapsulation resin composition.

A liquid encapsulation resin composition according to a seventh aspect of the present disclosure, which may be implemented in conjunction with any one of the first to sixth aspects, has, at 25° C., a viscosity equal to or greater than 1.0 Pa·s and equal to or less than 50.0 Pa·s.

The seventh aspect makes it easier to use the liquid encapsulation resin composition for fabricating the semiconductor device (1).

A liquid encapsulation resin composition according to an eighth aspect of the present disclosure, which may be implemented in conjunction with any one of the first to seventh aspects, has, at 25° C., a thixotropic index equal to or greater than 0.5 and equal to or less than 1.2.

According to the eighth aspect, the applicability of the liquid encapsulation resin composition onto the target tends to increase. In addition, the fillability of the liquid encapsulation resin composition into the gap between the semiconductor element (3) and the substrate (2) tends to increase as well while the semiconductor device (1) is being fabricated.

A liquid encapsulation resin composition according to a ninth aspect of the present disclosure, which may be implemented in conjunction with any one of the first to eighth aspects, has a viscosity equal to or greater than 0.01 Pa·s and equal to or less than 1.00 Pa·s at a temperature equal to or higher than 90° C. and equal to or lower than 170° C.

The ninth aspect allows the liquid encapsulation resin composition to have a viscosity falling within this range in the above-described temperature range, thus making it easier to fill the gap between the semiconductor element (3) and the substrate (2) while the semiconductor device (1) is being fabricated. Consequently, this allows the encapsulant (5) of the semiconductor device (1) to exert its performance fully.

In a liquid encapsulation resin composition according to a tenth aspect of the present disclosure, which may be implemented in conjunction with any one of the first to ninth aspects, the silica (A) is a spherical fused silica and has a maximum particle size equal to or less than 10.0 μm.

The tenth aspect makes it particularly easy for the liquid encapsulation resin composition to maintain its high flowability.

In a liquid encapsulation resin composition according to an eleventh aspect of the present disclosure, which may be implemented in conjunction with any one of the first to tenth aspects, the percentage of the silica (A) to the liquid encapsulation resin composition is equal to or greater than 40.0% by mass and equal to or less than 80.0% by mass.

The eleventh aspect enables not only decreasing the elastic modulus of a cured product of the liquid encapsulation resin composition but also adjusting the coefficient of linear expansion thereof to any desired numerical value.

In a liquid encapsulation resin composition according to a twelfth aspect of the present disclosure, which may be implemented in conjunction with any one of the first to eleventh aspects, a cured product of the liquid encapsulation resin composition has an elastic modulus equal to or greater than 2.0 GPa and equal to or less than 8.0 GPa.

The twelfth aspect enables improving the performance of the encapsulant (5) included in the semiconductor device (1) containing a cured product of the liquid encapsulation resin composition.

A liquid encapsulation resin composition according to a thirteenth aspect of the present disclosure, which may be implemented in conjunction with any one of the first to twelfth aspects, is used as a capillary underfill material.

The thirteenth aspect allows the underfill material to be applied through a capillary as fine as an injector needle from around the semiconductor element (3) such as a chip, thereby allowing the underfill material to be impregnated and permeated into the gap between the semiconductor element (3) and the substrate (2) by the capillary action. In this manner, a semiconductor device (1) including an encapsulant (5) containing a cured product of the liquid encapsulation resin composition may be fabricated.

A semiconductor device (1) according to a fourteenth aspect of the present disclosure includes: a substrate (2); a semiconductor element (3); and an encapsulant (5) filling a gap between the substrate (2) and the semiconductor element (3). The encapsulant (5) includes a cured product of the liquid encapsulation resin composition according to any one of the first to thirteenth aspects.

The fourteenth aspect may decrease the elastic modulus of the encapsulant (5) included in the semiconductor device (1) and increase the durability of the encapsulant (5) to temperature variations, thereby enabling reducing cracks to be caused at corner portions of the die included in the semiconductor device (1).

### EXAMPLES

Next, the present disclosure will be described in further detail by way of illustrative examples. Note that the examples to be described below are only examples of the present disclosure and should not be construed as limiting.

### Preparation of Liquid Encapsulation Resin Composition

Liquid encapsulation resin compositions representing respective examples and comparative examples were prepared by mixing together the components shown in Tables 1 and 2 (to be posted later). Following are the details of those components:

### <Silica>

Silica 1: silica prepared by sol-gel process and surface-treated with a silane coupling agent having a phenylamino group (having a mean particle size of 0.7 μm and a maximum particle size of 1.0 μm);
Silica 2: silica prepared by sol-gel process and surface-treated with a silane coupling agent having a phenylamino group (having a mean particle size of 0.1 μm and a maximum particle size of 0.3 μm); and
Silica 3: silica prepared by sol-gel process and surface-treated with a silane coupling agent having an epoxy group (having a mean particle size of 10 nm).

### Epoxy Resin

Epoxy 1: bisphenol F epoxy resin (product name: YDF-8170C manufactured by Nippon Steel Chemical & Materials Co., Ltd., having an epoxy equivalent of 160 g/eq); and
Epoxy 2: bisphenol A epoxy resin (product name: YDF-8125 manufactured by Nippon Steel Chemical & Material Co., Ltd., having an epoxy equivalent of 173 g/eq).

### <Curing Agent>

Amine-based curing agent 1: 3,3′-diethyl-4,4′-diaminodiphenylmethane (product name: Kayahard-AA manufactured by Nippon Kayaku Co., Ltd., having an amine equivalent of 64 g/eq); and
Amine-based curing agent 2: dimethylthiotoluenediamine (product name: EH105L manufactured by ADEKA Corporation, having an amine equivalent of 61 g/eq).

### <Curing Accelerator>

Curing accelerator 1: triphenylphosphine (product name: Hokuko TPP manufactured by Hokko Chemical Industry Co., Ltd.).

### <Triblock Copolymer>

Triblock copolymer 1: acrylic block copolymer (product name: Clarity LK9243 manufactured by Kuraray Co., Ltd.); and
Triblock copolymer 2: acrylic block copolymer (product name: Clarity KL-LK9333 manufactured by Kuraray Co., Ltd.).

### <Coupling Agent>

Coupling agent 1: epoxysilane (product name: A187 manufactured by Momentive Performance Materials Japan Co., Ltd.).

### Coloring Agent

Dye: Organic black coloring agent (product name: Kayaset Black A-N manufactured by Nippon Kayaku Co., Ltd.).

### Evaluation of Liquid Encapsulation Resin Composition

Next, evaluation items of the liquid encapsulation resin compositions according to respective examples and comparative examples will be described one by one.

### <Viscosity>

First, each liquid encapsulation resin composition had its viscosity measured using a Brookfield viscometer (model number: TVB-10 manufactured by Toki Sangyo Co., Ltd.) with the temperature set at 25° C. and the number of revolutions set at 10.0 rpm. The rotor used at this time was No. 6. The values of viscosity thus measured are shown in Tables 1 and 2.

### <Thixotropic Index>

The viscosity of the liquid encapsulation resin composition was measured at a number of revolutions of 1.0 rpm in the same way as in the viscosity measurement described above. The thixotropic index of the liquid encapsulation resin composition was calculated by the following equation based on the viscosity at the number of revolutions of 1.0 rpm and the viscosity at the number of revolutions of 10.0 rpm:

Thixotropic index=viscosity at number of revolutions of 1.0 rpm/viscosity at number of revolutions of 10.0 rpm

The thixotropic indices thus obtained are shown in Tables 1 and 2.

### <Elastic Modulus>

Each liquid encapsulation resin composition was sandwiched between a pair of glass panes, heated to a heating temperature of 100° C. for a heating duration of 2 hours, and then was further heated to a heating temperature of 165° C. for a heating duration of 2 hours to cause the liquid encapsulation resin composition to be cured and thereby make a test piece of a cured product of the liquid encapsulation resin composition having a length of 70 mm, a width of 10 mm, and a thickness of 3 mm. The flexural modulus at 25° C. of the test piece thus obtained was measured in compliance with the JIS K 6911 standard. The values thus obtained are shown in Tables 1 and 2.

### <Infiltration Property>

After the upper surface of a smooth glass pane had been cleaned by subjecting the glass pane to argon gas plasma processing using a plasma cleaner, glass pieces were combined on the upper surface of the glass pane to form a tunnel-shaped flow channel with an inner wall made of glass and with both ends open. A cross section of the flow channel had a rectangular shape with dimensions of 20 μm in height and 20 mm in width.

While the glass pane was heated to have its temperature kept at 90° C., the liquid encapsulation resin composition at a temperature of 25° C. was discharged from a syringe onto around one end of the flow channel on the upper surface of the glass pane, thereby allowing the liquid encapsulation resin composition to infiltrate the flow channel. The liquid encapsulation resin composition was replenished as appropriate to prevent the amount of the liquid encapsulation resin composition around one end of the flow channel from running short. The time it took for the liquid encapsulation resin composition in the flow channel to reach a distance of 20 mm from the one end of the flow channel since the beginning of the test was measured and used as the evaluation result of the infiltration test. The values measured at this time are shown in Tables 1 and 2.

### <Viscosity at 100° C.>

The viscosity of each liquid encapsulation resin composition at 100° C. was measured using a rotary rheometer (model number: MCR302 manufactured by Anton Paar Japan Ltd.). As for the measurement condition at this time, the shear rate was set at 4/s. A parallel plate (PP) jig with φ of 25 mm was used. The values thus obtained are shown in Tables 1 and 2.

TABLE 1

| | | | Examples | | | | | | |
|---|---|---|---|---|---|---|---|---|---|
| | | | 1 | 2 | 3 | 4 | 5 | 6 | 7 |
| Components | Silica (A) | Silica 1 | 111.0 | 111.0 | 111.0 | 111.0 | 111.0 | 111.0 | 111.0 |
| (parts by | | Silica 2 | 45.0 | 45.0 | 45.0 | 45.0 | 45.0 | 45.0 | 45.0 |
| mass) | | Silica 3 | 4.8 | 4.8 | 4.8 | 4.8 | 4.8 | 4.8 | 4.8 |
| | Epoxy resin (B) | Epoxy 1 | 85.3 | 83.3 | 81.6 | 81.6 | 83.3 | 83.3 | 83.3 |
| | | Epoxy 2 | 9.5 | 9.3 | 9.0 | 9.0 | 9.3 | 9.3 | 9.3 |
| | Curing agent (C) | Amine-based | 26.0 | 25.3 | 24.7 | 24.7 | 25.3 | 25.3 | 24.7 |
| | | Curing agent 1 | | | | | | | |
| | | Amine-based | 11.0 | 10.8 | 10.5 | 10.5 | 10.8 | 10.8 | 10.5 |
| | | Curing agent 2 | | | | | | | |
| | Curing | Curing | 0.4 | 0.4 | 0.4 | 0.4 | 0.4 | 0.4 | 0.4 |
| | accelerator (D) | accelerator 1 | | | | | | | |
| | Triblock | Triblock | 3.5 | 7.0 | 11.0 | 1.3 | — | — | — |
| | copolymer (E) | copolymer 1 | | | | | | | |
| | | Triblock | — | — | — | — | 1.4 | 7.0 | 11.0 |
| | | copolymer 2 | | | | | | | |
| | Coupling agent | Coupling agent 1 | 1.8 | 1.8 | 1.8 | 1.8 | 1.8 | 1.8 | 1.8 |
| | Coloring agent | Dye | 1.7 | 1.7 | 1.7 | 1.7 | 1.7 | 1.7 | 1.7 |
| | Total | | 299.9 | 300.3 | 301.4 | 291.7 | 294.7 | 300.3 | 303.4 |
| | Item | Unit | | | | | | | |
| Evaluation | Viscosity (at 10.0 | Pa · s | 16.2 | 19.3 | 25.7 | 13.0 | 14.0 | 24.0 | 34.0 |
| | rpm) | | | | | | | | |
| | Thixotropic index | — | 1.0 | 1.1 | 1.1 | 1.0 | 1.0 | 1.0 | 1.1 |
| | (1.0 rpm/10.0 rpm) | | | | | | | | |
| | Elastic modulus | GPa | 6.3 | 5.1 | 4.0 | 6.4 | 6.4 | 6.2 | 5.2 |
| | Infiltration property | sec | 190 | 310 | 490 | 160 | 180 | 230 | 550 |
| | Viscosity (at 100° C.) | Pa · s | 0.09 | 0.17 | 0.26 | 0.08 | 0.09 | 0.13 | 0.25 |

TABLE 2

| | | | Comparative examples | | |
|---|---|---|---|---|---|
| | | | 1 | 2 | 3 |
| Components | Silica (A) | Silica 1 | 111.0 | 111.0 | 111.0 |
| (parts by mass) | | Silica 2 | 45.0 | 45.0 | 45.0 |
| | | Silica 3 | 4.8 | 4.8 | 4.8 |
| | Epoxy resin (B) | Epoxy 1 | 87.3 | 81.6 | 79.8 |
| | | Epoxy 2 | 9.8 | 9.0 | 8.8 |
| | Curing agent (C) | Amine-based curing agent 1 | 26.5 | 24.7 | 24.1 |
| | | Amine-based curing agent 2 | 11.3 | 10.5 | 10.2 |
| | Curing accelerator (D) | Curing accelerator 1 | 0.4 | 0.4 | 0.4 |
| | Triblock copolymer (E) | Triblock copolymer 1 | — | 0.7 | — |
| | | Triblock copolymer 2 | — | — | 12.3 |
| | Coupling agent | Coupling agent 1 | 1.8 | 1.8 | 1.8 |
| | Coloring agent | Dye | 1.7 | 1.7 | 1.7 |
| | Total | | 299.5 | 291.1 | 299.8 |
| Evaluation | Item | Unit | | | |
| | Viscosity (at 10.0 rpm) | Pa · s | 11.0 | 13.0 | 53.4 |
| | Thixotropic index | — | 1.0 | 1.0 | 1.3 |
| | (1.0 rpm/10.0 rpm) | | | | |
| | Elastic modulus | GPa | 7.5 | 7.2 | 2.5 |
| | Infiltration property | sec | 120 | 130 | >900 |
| | Viscosity (at 100° C.) | Pa · s | 0.06 | 0.06 | 0.45 |

Each of Comparative Examples 1 and 2 had a smaller content of triblock copolymer (E) than any of Examples 1-7, and therefore, an uncured product thereof exhibited approximately the same degree of flowability as the uncured product of any of Examples 1-7. However, these results reveal that a cured product with a low elastic modulus could not be obtained in any of Comparative Examples 1 and 2. In addition, Comparative Example 3 had a larger content of triblock copolymer (E) than any of Examples 1-7. Thus, these results reveal that the flowability of an uncured product of Comparative Example 3 decreased significantly.

### REFERENCE SIGNS LIST

1 Semiconductor Device
2 Substrate
3 Semiconductor Element
5 Encapsulant

1. A liquid encapsulation resin composition containing a silica (A), an epoxy resin (B), a curing agent (C), a curing accelerator (D), and a triblock copolymer (E) expressed by the following formula (1):
X—Y—X (1)
where X is a segment block configured as a polymer of methyl methacrylate and Y is a segment block configured as a polymer of monomer components containing 2-ethylhexyl acrylate, and
percentage of the triblock copolymer (E) to a total of the epoxy resin (B), the curing agent (C), and the curing accelerator (D) being equal to or greater than 1.0% by mass and equal to or less than 9.5% by mass.

2. The liquid encapsulation resin composition of claim 1, wherein
the monomer components further contain butyl acrylate.

3. The liquid encapsulation resin composition of claim 1, wherein
the triblock copolymer (E) has a weight average molecular weight equal to or greater than 40,000 and equal to or less than 100,000.

4. The liquid encapsulation resin composition of claim 1, wherein
the epoxy resin (B) is in liquid form at 25° C.

5. The liquid encapsulation resin composition of claim 1, wherein
the curing agent (C) contains an aromatic amine-based curing agent (C-1).

6. The liquid encapsulation resin composition of claim 1, wherein
a functional group equivalent ratio of the epoxy resin (B) to the curing agent (C) is equal to or greater than 0.6 and equal to or less than 1.4.

7. The liquid encapsulation resin composition of claim 1, wherein
the liquid encapsulation resin composition has, at 25° C., a viscosity equal to or greater than 1.0 Pa·s and equal to or less than 50.0 Pa·s.

8. The liquid encapsulation resin composition of claim 1, wherein
the liquid encapsulation resin composition has, at 25° C., a thixotropic index equal to or greater than 0.5 and equal to or less than 1.2.

9. The liquid encapsulation resin composition of claim 1, wherein
the liquid encapsulation resin composition has a viscosity equal to or greater than 0.01 Pa·s and equal to or less than 1.00 Pa·s at a temperature equal to or higher than 90° C. and equal to or lower than 170° C.

10. The liquid encapsulation resin composition of claim 1, wherein
the silica (A) is a spherical fused silica, and
the silica (A) has a maximum particle size equal to or less than 10.0 μm.

11. The liquid encapsulation resin composition of claim 1, wherein
percentage of the silica (A) to the liquid encapsulation resin composition is equal to or greater than 40.0% by mass and equal to or less than 80.0% by mass.

12. The liquid encapsulation resin composition of claim 1, wherein
a cured product of the liquid encapsulation resin composition has an elastic modulus equal to or greater than 2.0 GPa and equal to or less than 8.0 GPa.

13. The liquid encapsulation resin composition of claim 1, wherein
the liquid encapsulation resin composition is used as a capillary underfill material.

14. A semiconductor device comprising: a substrate; a semiconductor element; and an encapsulant filling a gap between the substrate and the semiconductor element,
the encapsulant including a cured product of the liquid encapsulation resin composition of claim 1.
